(19) United States
(12) Patent Application Publication
(10) Pub. No.: US 2014/0300346 A1
(43) Pub. Date: Oct. 9, 2014

(54) Electrical Current Shunt

(71) Applicant: John Zhang, College Station, TX (US)

(72) Inventor: John Zhang, College Station, TX (US)

(21) Appl. No.: 14/246,531

(22) Filed: Apr. 7, 2014

Related U.S. Application Data
(60) Provisional application No. 61/809,928, filed on Apr. 9, 2013.

(51) Int. Cl. G01R 19/00

(52) U.S. Cl. CPC G01R 19/0092
USPC 324/120

(57) ABSTRACT

A distributed current shunt circuit evenly divides one large shunt into a number of parallel connected, smaller shunts, each having the same resistance value. With proper electronics such as an instrumentation amplifier for each shunt, an operational amplifier, and precision resistors, the device measures the total current by adding or averaging voltage readings of these small shunts.

This application claims the benefit of U.S. Provisional Application No. 61/809,928 filed Apr. 9, 2013.

### FIELD OF THE INVENTION

The present invention relates generally to the field of electrical shunts, and, more particularly, to the field of high-current electrical shunts. Even more particularly, the invention relates to a plurality of relatively small shunts in parallel to replace the single large shunt commonly in use in the art.

### BACKGROUND OF THE INVENTION

In the field of metrology, the measurement of a high current accurately typically includes the use of a shunt. A shunt is commonly a large capacity, low resistance resistor with four terminals—two terminals for passing current and two terminals for measuring the voltage drop of the current across the shunt using Ohm's Law E=I R.

Traditional shunt design focuses on improving the mechanical structure of the circuit to which the shunt is applied in order to eliminate the error caused by the uncertainty caused by unpredictable current distribution within one large shunt. Furthermore, current distribution over a large current shunt is more likely to be affected by change of temperature and stress than a smaller shunt.

Most traditional shunts are actually made by paralleling a number of small resistance pieces but it fails to measure voltage drop of each of these small shunt pieces, instead it assumes or tries to make even current distribution over these pieces and use only one voltage measurement to represent the whole current.

The present invention is directed to solving these and other drawbacks in the art.

### SUMMARY OF THE INVENTION

To solve these needs in the art, the present invention defines a device that evenly divides one large shunt into a number of parallel connected, smaller shunts, each having the same resistance value. With proper electronics, the device measures the total current by adding or averaging voltage readings of these small shunts. In a preferred embodiment, the device includes such electronic components as an instrumentation amplifier, an operational amplifier, and precision resistors. With the use of an instrumentation amplifier, the signal to be measured can be amplified accurately so that the method of measuring the shunt signal can be much more precise than the method of measurement without such an instrumentation amplifier.

The underlying principals of this invention include several factors. First. a low current shunt is easier to manufacture than a large current shunt. Further, a small capacity shunt exhibits a lower resistance value drift caused by working conditions such as temperature change and mechanical stress. Second, the averaging effect of multiple sensors reduces the effects of variations of devices within manufacturing tolerances which can result in uncertainty of the device and its measurements.

Compared to making a traditional large current shunt, it is easier to make a distributed current shunt using IC chips to realize high precision, lower drift and low cost.

These and other features and advantages of this invention will be apparent to those of skill in the art from a review of the following detailed description along with the accompanying drawing figures.

### BRIEF DESCRIPTION OF THE DRAWINGS

FIG. 1 is a schematic diagram of a known shunt circuit.

FIG. 2 is a schematic diagram of a distributed shunt arranged in accordance with the teachings of this invention.

### DETAILED DESCRIPTION OF A PREFERRED EMBODIMENT

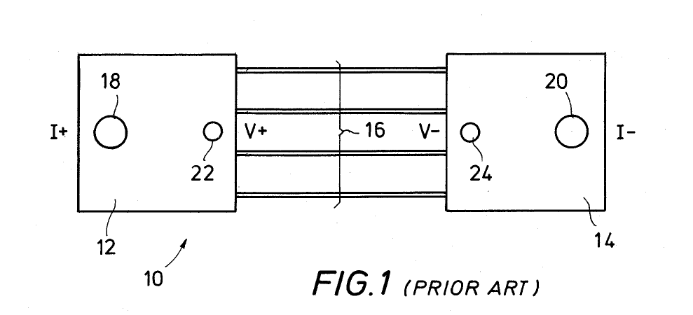

FIG. 1 illustrates a prior art current shunt circuit 10. The circuit 10 comprises a first bus bar 12 and a second bus bar 14, connected by a resistant strip 16 of known resistance. The circuit further includes four terminals, including a first or positive current terminal 18 and a second or negative current terminal 20. The voltage potential between the bus bars 12 and 14 is taken between a first or positive voltage terminal 22 and a second or negative voltage terminal 24.

While simple in construction, the current shunt circuit 10 suffers the drawbacks described above.

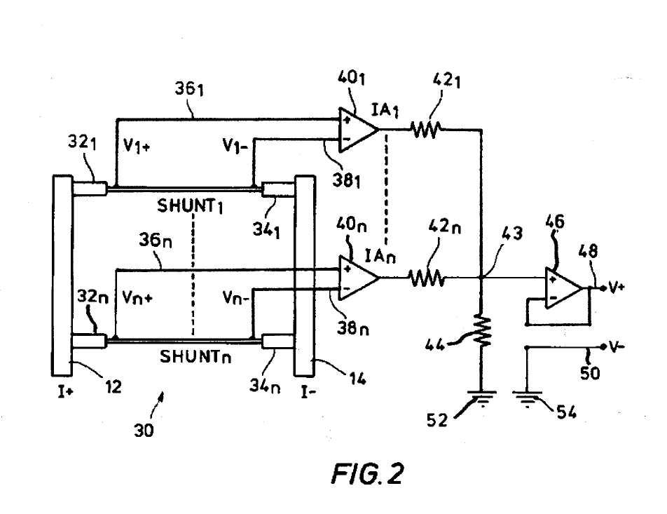

FIG. 2 illustrates a distributed shunt circuit 30 of this invention. The shunt circuit 30 includes the first bus bar 12 and the second bus bar 14 as previously described. A plurality, (i.e. n), shunts run between the first bus bar 12 and the second bus bar 14. A first shunt is designated shunt₁ in FIG. 2 and the nth shunt is designated shuntₙ. Thus, the current carrying capacity of the resistant strip 16 of FIG. 1 is divided into n shunts, each having an equal value.

At a first end 32₁ of shunt₁ is a first or positive voltage terminal V₁₊ and at a second end 34₁ of shunt₁ is a second or negative voltage terminal V₁₋. Similarly, at a first end 32ₙ of shunt, is a first or positive voltage terminal Vₙ₊, and at a second end 34ₙ of shunt, is a second or negative voltage terminal Vₙ₋. A first conductor 36₁ and a second conductor 38₁ couple the respective terminals to a first instrumentation amplifier 40₁; a first n^{th} conductor 36ₙ and a second n^{th} conductor 38ₙ couple the respective terminals to an n^{th} instrumentation amplifier 40ₙ; and so on for all of the n shunts. The instrumentation amplifiers each feed a dedicated resistor 42₁ through 42ₙ, respectively. The current from the resistors is summed at a node 43, which is coupled to ground 52 through a potential resistor 44. The node 43 is coupled to the non-inverting input of an operational amplifier 46, while the inverting input of the op-amp 46 is coupled to ground 54. The potential between the bus bars 12 and 14 is thus measured between the op-amp output 48 and a terminal 50 coupled to ground 54.

Thus, it will be appreciated by those of skill in the art that the distributed shunt just described can be realized with n discrete shunts and IC chips or it can be highly integrated into a much smaller package for massive production. The circuit can be used to make a compact, high precision current meter or coulometer.

Further, the shunt circuit of this invention divides one large shunt into a number of small shunts, each with voltage terminals and measurements. The circuit sums those voltage measurements to represent the total current. The resultant distributed current shunt is an integrated and active shunt with electronics and power inside instead of a simple passive shunt without electronics. The integrated distributed shunt may have the same two current terminals and two voltage terminals and similar appearance and functionality as a traditional shunt. The distributed shunt can be calibrated and used in the same way as a traditional shunt.

The output voltage signal of the shunt can be amplified and filtered so that it has better resolution and signal to noise ratio. The voltage signal may also represent a higher resistance value for the current than its actual resistance value. For the same performance, the distributed current shunt can be made more compact, lighter, and easier to handle.

The principles, preferred embodiment, and mode of operation of the present invention have been described in the foregoing specification. This invention is not to be construed as limited to the particular forms disclosed, since these are regarded as illustrative rather than restrictive. Moreover, variations and changes may be made by those skilled in the art without departing from the spirit of the invention.

I claim:

1. A distributed current shunt comprising more than one smaller shunt, each current through each smaller shunt being sensed and treated to get total current through the integrated, distributed shunt.

2. The shunt of claim 1, wherein the shunt is integrated onto a single integrated circuit chip.

3. A distributed shunt comprising:
a first bus bar;
a second bus bar;
a plurality of shunts between the first and second bus bars, each of the plurality of shunts having the same resistance value;
a first voltage terminal at a first bus bar end of each of the plurality of shunts;
a second voltage terminal at a second bus bar end of each of the plurality of shunts;
a plurality of instrumentation amplifiers, the number of instrumentation amplifiers equal to the number of shunts;
a plurality of first conductors electrically coupling the first voltage terminals to a respective first inputs of the instrumentation amplifiers;
a plurality of second conductors electrically coupling the second voltage terminals to a respective second inputs of the instrumentation amplifiers;
a dedicated resistor coupled to the current output of each of the instrumentation amplifiers;
a summing node to receive the current from the dedicated resistors;
a potential resistor to determine the voltage difference between the summing node and ground; and
an operational amplifier coupled to the summing node, the output of the operational amplifier function of the total current through the plurality of shunts.
